(19) United States
(12) Patent Application Publication
(10) Pub. No.: US 2026/0291238 A1
(43) Pub. Date: Sep. 24, 2026

(54) METHOD AND APPARATUS FOR PREVENTING OVERDISCHARGE OF BATTERY IN POWER SUPPLY SYSTEM

(71) Applicant: HANWHA SOLUTIONS CORPORATION, Seoul (KR)

(72) Inventors: Min Ho AHN, Seoul (KR); Seung Gwon KIM, Seoul (KR)

(21) Appl. No.: 19/564,458

(22) Filed: Mar. 12, 2026

(30) Foreign Application Priority Data
Mar. 24, 2025 (KR) 10-2025-0037608

(51) Int. Cl. H02J 3/32; H02J 3/007; H02J 3/38; H02J 7/00; H02J 7/60; H02J 7/63; H02J 7/90; H02J 101/24

(52) U.S. Cl. CPC H02J 3/32; H02J 3/007; H02J 3/38; H02J 7/63; H02J 7/663; H02J 7/865; H02J 7/933; H02J 2101/24; H02J 2207/20

(57) ABSTRACT

Provided is a method and apparatus for preventing battery overdischarge in a power supply system. The method of preventing overdischarge of a battery in a power supply system includes controlling an operation of the battery in response to a state of charge (SOC) of the battery being in a first range, determining at least one of whether charging of the battery using power generated from a power generation device included in the power supply system is possible or whether charging of the battery using power supplied from an external power grid is possible, in response to the SOC of the battery being in a second range, and performing, based on a result of the determining, at least one of changing of an electrical connection relationship between devices included in the power supply system or charging of the battery.

### CROSS-REFERENCE TO RELATED APPLICATION

This application is based on and claims priority under 35 U.S.C. §119 to Korean Patent Application No. 10-2025-0037608, filed on Mar. 24, 2025, the Ministry of Intellectual Property, Republic of Korea, the disclosure of which is incorporated by reference herein in its entirety.

### BACKGROUND

### 1. Field

The present disclosure relates to a method and apparatus for preventing battery overdischarge in a power supply system.

### 2. Description of the Related Art

In case that a battery experiences overdischarge where a voltage thereof drops below a certain level, an internal chemical reaction within a battery cell may undergo an irreversible change, potentially degrading performance and lifespan of the battery. In this regard, there may exist technology that prevents battery overdischarge by tripping the battery based on real-time monitoring of various battery parameters such as a voltage of the battery, a state of charge (SOC), etc.

Meanwhile, in a power supply system including a power-generation device, a load, and an energy storage device, various power flow scenarios may occur due to fluctuation of generated energy, variability of a load demand, and whether the power supply system is connected to an external power grid.

To prevent overdischarge of the battery using an algorithm for tripping the battery in case that the SOC or voltage of the battery simply decreases a specific level, various power flow scenarios of the power supply system may not be sufficiently reflected. For example, even in a situation where battery charging may be performed using generated energy of the power generation device or energy supplied from the external power grid, unnecessary battery protection may be executed, which may consequently degrade the stability of power supply.

Accordingly, there is a need for a method to prevent battery overdischarge by comprehensively considering fluctuation of generated energy, a state of the load, and power grid connection, thereby preventing battery overdischarge while maintaining stable power supply.

The above-mentioned background technology is technical information that the inventor possessed for deriving the disclosure or acquired in the process of deriving the disclosure, and may not be necessarily said to be known art disclosed to the general public before filing the application of the present disclosure.

### SUMMARY

The present disclosure provides a method and apparatus for preventing overdischarge of a battery in a power supply system. The present disclosure also provides a computer-readable recording medium having recorded thereon a program for executing the method on a computer. The technical problems of the present disclosure are not limited to the aforementioned technical features, and other unstated technical problems may be inferred from embodiments of the disclosure below.

According to a first aspect of the present disclosure, a method of preventing overdischarge of a battery in a power supply system includes controlling an operation of the battery in response to a state of charge (SOC) of the battery being in a first range, determining at least one of whether charging of the battery using power generated from a power generation device included in the power supply system is possible or whether charging of the battery using power supplied from an external power grid is possible, in response to the SOC of the battery being in a second range, and performing, based on a result of the determining, at least one of changing of an electrical connection relationship between devices included in the power supply system or charging of the battery.

According to a second aspect of the present disclosure, a computer-readable recording medium has recorded thereon a program for executing the method according to the first aspect on a computer.

According to a third aspect of the present disclosure, an apparatus for preventing overdischarge of a battery in a power supply system includes at least one memory and at least one processor, in which the at least one processor is configured to control an operation of the battery, in response to a state of charge (SOC) of the battery being in a first range, determine at least one of whether charging of the battery using power generated from a power generation device included in the power supply system is possible or whether charging of the battery using power supplied from an external power grid is possible, in response to the SOC of the battery being in a second range, and perform, based on a result of the determination, at least one of changing of an electrical connection relationship between devices included in the power supply system or charging of the battery.

Other aspects, features, and advantages than those described above will be clear from the accompanying drawings, the claims, and the detailed description below.

### BRIEF DESCRIPTION OF THE DRAWINGS

The above and other aspects, features, and advantages of certain embodiments of the disclosure will be more apparent from the following description taken in conjunction with the accompanying drawings in which:

FIG. 1 is a view for schematically describing a power supply system;

FIG. 2 shows an example of a power supply system according to an embodiment;

FIG. 3 shows an example of a power supply system according to another embodiment;

FIG. 4 is a view for describing an electrical connection relationship between components of a power supply system according to an embodiment;

FIG. 5 is a flowchart of a method of preventing overdischarge of a battery according to an embodiment;

FIG. 6 is a flowchart of a method of preventing overdischarge of a battery according to an embodiment;

FIG. 7 is a flowchart of a method of preventing overdischarge of a battery according to another embodiment; and

FIG. 8 is a block diagram of a main controller according to an embodiment.

### DETAILED DESCRIPTION

Advantages and features of the present disclosure, and a method of achieving them will be apparent with reference to the embodiments described in detail in conjunction with the drawings. However, the present disclosure is not limited to the embodiments presented below, but may be implemented in various different forms, and should be understood to include all transformations, equivalents, and substitutes included in the spirit and technical scope of the present disclosure. Embodiments presented below are provided to complete the disclosure of the present disclosure and perfectly inform those of ordinary skill in the art of the category of the present disclosure. It should be understood, however, that this is not intended to limit the present disclosure to a particular embodiment of the present disclosure, and should be understood to include all changes, equivalents, and alternatives falling within the spirit and scope of the present disclosure.

The term used herein is used to describe particular embodiments, and is not intended to limit the present disclosure. Singular forms include plural forms unless apparently indicated otherwise contextually. It should be understood that the term "include", "have", or the like used herein is to indicate the presence of features, numbers, steps, operations, elements, parts, or a combination thereof described in the specifications, and does not preclude the presence or addition of one or more other features, numbers, steps, operations, elements, parts, or a combination thereof.

Some embodiments of the present disclosure may be represented by functional block configurations and various processing steps. Some or all of the functional blocks may be implemented with various numbers of hardware and/or software configurations executing particular functions. In some embodiments, the functional blocks of the present disclosure may be implemented by one or more microprocessors or circuit configurations for certain functions. In some embodiments, functional blocks of the present disclosure may be implemented in various programming or scripting languages. Functional blocks may be implemented as algorithms running on one or more processors. The present disclosure may employ related art for electronic environment setting, signal processing, and/or data processing, etc. The term such as "mechanism", "element", "means", or "configuration" may be used broadly and may not be limited to mechanical and physical configurations.

Additionally, connection lines or connection members between components shown in the drawings merely exemplify functional connections and/or physical or circuit connections. In an actual device, connections between components may be represented by various replaceable or additional functional connections, physical connections, or circuit connections.

Hereinafter, the present disclosure will be described in detail with reference to the attached drawings.

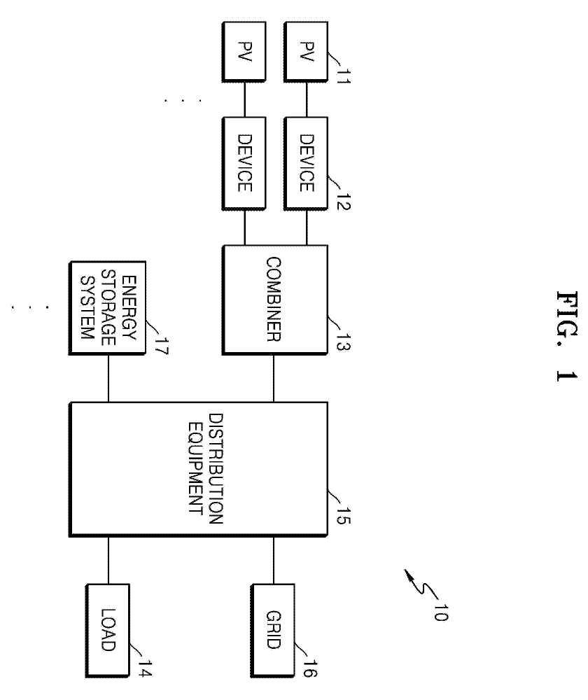

FIG. 1 is a view for schematically describing a power supply system.

Referring to FIG. 1, a power supply system 10 may include a photovoltaic module 11, a device 12, a load 14, and/or distribution equipment 15. The power supply system 10 may be connected to an external power grid 16.

At least one photovoltaic module 11 may be installed on the roof or exterior wall of a building to generate power. A plurality of photovoltaic modules 11 may be connected to form a photovoltaic module array.

The photovoltaic module 11 may be connected to the device 12. For example, at least one device 12 may be connected to each photovoltaic module 11. As an example, in case that one device 12 is connected to each photovoltaic module 11, the number of devices 12 constituting the power supply system 10 may be equal to the number of photovoltaic modules 11.

The device 12 may be a power conditioning system or power conversion system (PCS) that performs power conversion for power generated from the photovoltaic module 11. For example, the device 12 may perform selected conversion on the power generated from the photovoltaic module 11 and supply the converted power to other components of the power supply system 10 (e.g., the power grid 16 and/or the load 14, etc.).

The device 12 may be a module level power electronics (MLPE) device. For example, the device 12 may be an optimizer or a micro inverter (MI).

For example, in case that the device 12 is an optimizer, the device 12 may regulate the power generated from the photovoltaic module 11 and output the regulated power to an inverter (e.g., a string inverter). Current converted by the inverter (e.g., direct current converted into alternating current) may be output to the power grid 16 or the load 14.

As another example, in case that the device 12 is a micro inverter, the device 12 may convert the power generated from the photovoltaic module 11 (e.g., convert direct current into alternating current). The current converted in the device 12 may be output to the power grid 16 or the load 14.

Depending on a need, the power supply system 10 may further include a combiner 13. At least a part of the device 12 may be connected to the distribution equipment 15 through the combiner 13. For example, power output from a plurality of devices 12 may be combined into one output by the combiner 13 and supplied to the distribution equipment 15.

The device 12 and the distribution equipment 15 may be connected by a power path that does not include the combiner 13, and at least one device 12 may be connected to the distribution equipment 15 by a power path that does not include the combiner 13, and at least one other device 12 may be connected to the distribution equipment 15 through the combiner 13.

The combiner 13 may control voltage, current and/or power output from the device 12 according to a power supply state of the photovoltaic module 11, the device 12, and/or the power grid 16, and set the operation mode of the combiner 13 to a diagnosis mode or a driving mode, etc.

The combiner 13 may include an energy management system (EMS) that controls the operation of the combiner 13. The EMS may control voltage, current and/or power supplied to or output from the device 12 according to a power supply state of the photovoltaic module 11, the device 12, and/or the power grid 16, and set the operation mode of the combiner 13 to the diagnosis mode or the driving mode, etc.

The load 14 may refer to an object that is installed in an electricity receiver such as a house, commercial facility, factory, etc., and operates by receiving at least one of energy generated by the photovoltaic module 11, energy stored in an energy storage device 17, and/or energy supplied from the power grid 16. For example, in case that the electricity receiver receiving power is a house, the load 14 may include home appliances such as a washing machine, a refrigerator, a TV, etc.

The power grid 16 may include an infrastructure system for generating, transmitting, and distributing power. For example, the power grid 16 may include the infrastructure system such as power plants, substations, power lines, etc. The power grid 16 may transmit electric energy generated at a power plant to the power supply system 10 or transmit surplus power generated in the power supply system 10 to the outside of the power supply system 10.

For example, commercial power transmitted from the power grid 16 through a power pole may be supplied to the power receiver through a transformer. The power supply system 10 may be implemented as an off-grid system that is not connected to the power grid 16.

The power supply system 10 may further include at least one energy storage device 17. Depending on a need, the power supply system 10 may further include a plurality of energy storage devices 17. The energy storage device 17 may receive and store power generated from the photovoltaic module 11 and/or power transmitted from the power grid 16. The energy storage device 17 may efficiently supply power by storing power and supplying power to the load 14 when the load 14 needs the power.

The energy storage device 17 may include a battery that stores power and a power conversion module. The battery includes a battery management system (BMS) that monitors a state of charge (SOC), a state of health (SOH), voltage and/or current of the battery, performs diagnosis on the battery, and performs a safety function such as current interruption, etc.

The power conversion module may be a PCS that performs conversion between battery-side power and opposite-side power. For example, the PCS may convert between direct current on the battery side and alternating current on the opposite side. As an example, the PCS may include a bidirectional DC-DC converter that is connected to the battery to convert voltage, and a bidirectional inverter that connects the DC-DC converter to the outside of the energy storage device 17.

The energy storage device 17 may further include an EMS that controls the operation of the energy storage device 17. The EMS may control the voltage, current and/or power supplied to or output from the energy storage device 17 according to the power supply state of the battery and/or the power grid 16, and may set the operation mode of the energy storage device 17 to the diagnosis mode or the driving mode, etc.

Depending on a need, the EMS coupled to a selected component of the power supply system 10 may not only control the operation of a selected component, but may also control operations of other components of the power supply system 10. For example, the EMS coupled to the combiner 13 or the EMS coupled to the energy storage device 17 may control both the operation of the combiner 13 and the operation of the energy storage device 17.

The distribution equipment 15 may provide electrical connection between components of the power supply system 10 and may control a power flow of the power supply system 10. For example, the distribution equipment 15 may electrically connect the photovoltaic module 11 and the load 14. As an example, the distribution equipment 15 may be connected to the device 12 connected to the photovoltaic module 11 to electrically connect the photovoltaic module 11 to the load 14. Depending on a need, the distribution equipment 15 may be further connected to at least one of the energy storage device 17 and the power grid 16.

For example, the distribution equipment 15 may be a distribution panel that distributes power within the power supply system 10. As an example, the distribution equipment 15 may be a master service panel (MSP) that distributes the power generated from the photovoltaic module 11 to the load 14, etc.

As another example, the distribution equipment 15 may be a main controller that performs power distribution within the power supply system and controls each device 12. For example, the main controller may include a switch, a circuit breaker, and a control unit. The switch, the circuit breaker and the control unit may each be implemented as an independent device, or at least some of the switch, the circuit breaker and the control unit may be included in a single device.

The main controller may include a switch that controls electrical connection between components connected to the main controller, such as the device 12 and the load 14. For example, the main controller may include a relay, a power semiconductor, etc., that provides or disconnects an electrical connection to the device 12 and/or the energy storage device 17 depending on the operating state of each component of the power supply system 10.

The main controller may perform rapid shutdown to stop power generation of the photovoltaic module 11 in an emergency situation such as overcurrent occurrence in the power supply system 10, etc. To this end, the main controller may include a circuit breaker that disconnects a connection between the device 12 and the load 14.

The main controller may include a control unit that generally controls the operation of the main controller. The control unit may control the operations of other components of the power supply system 10 (the device 12, the energy storage device 17, or the like) as well as the main controller.

The control unit may perform control on the voltage, current and/or power output from or supplied to each component according to the power supply state of the photovoltaic module 11, the device 12, the combiner 13, the load 14, the power grid 16 and/or the energy storage device 17. The control unit may set the operation mode of the main controller, the device 12 and/or the energy storage device 17 to the diagnosis mode, the driving mode, etc.

For example, the control unit may control the photovoltaic module 11, the device 12, the combiner 13 and/or the energy storage device 17, based on the state of the power supply system 10. As an example, the control unit may control other components of the power supply system 10 by causing the main controller to communicate with other components of the power supply system 10 (e.g., the device 12, etc.). Communication between the main controller and other components of the power supply system 10 may be performed using power line communication (PLC), but the present disclosure is not limited thereto.

As an example, the control unit may control the device 12 according to the power generation state of the photovoltaic module 11. For example, the main controller may receive a control command from a server that monitors the power generation state of the photovoltaic module 11, and the control unit may control the device 12 according to the control command.

The main controller may supply power to at least a part of the load 14 in case that power supply from the power grid 16 is not smooth (e.g., in an off-grid situation, etc.). For example, in case that power supply from the power grid 16 is not smooth, the main controller may preferentially supply power generated from the photovoltaic module 11 and/or power stored in the energy storage device 17 to a backup load that has a relatively high need for stable power supply.

The power supply system 10 may further include an auxiliary power generation device (e.g., a diesel generator, etc.) that generates power in a separate manner other than photovoltaic power generation. For example, an auxiliary power generation device may be further connected to the distribution equipment 15. In case that the photovoltaic module 11 and the energy storage device 17 may not meet the power required by the backup load due to environmental factors such as a time of day or weather, the main controller may supply the power generated from the auxiliary power generation device to the backup load.

The control unit may be implemented by at least one processor. The processor may process a command of a computer program by performing basic arithmetic, logic, and input/output operations. The command may be provided from an internal memory of the main controller or from an external device. The processor may generally control operations of other components included in the main controller.

The processor may perform at least some of data analysis, processing, and result information generation for performing the above-described operations using at least one of machine learning, a neural network, or a deep learning algorithm as a rule-based or artificial intelligence algorithm. Examples of neural networks may include architecture-based neural network models such as a convolutional neural network (CNN), a deep neural network (DNN), and a recurrent neural network (RNN).

For example, the processor may be implemented as an array of a plurality of logic gates, or may be implemented as a combination of a general-purpose microprocessor and a memory storing a program executable on the microprocessor. For example, a processor may include a general purpose processor, a central processing unit (CPU), a microprocessor, a digital signal processor (DSP), a controller, a microcontroller, a state machine, etc.

In some environments, the processor may include an application specific integrated circuit (ASIC), a programmable logic device (PLD), a field programmable gate array (FPGA), etc. For example, the processor may refer to a combination of a DSP and a microprocessor, a combination of a plurality of microprocessors, a combination of one or more microprocessors combined with a DSP core, or a combination of processing devices such as any combination of other such components.

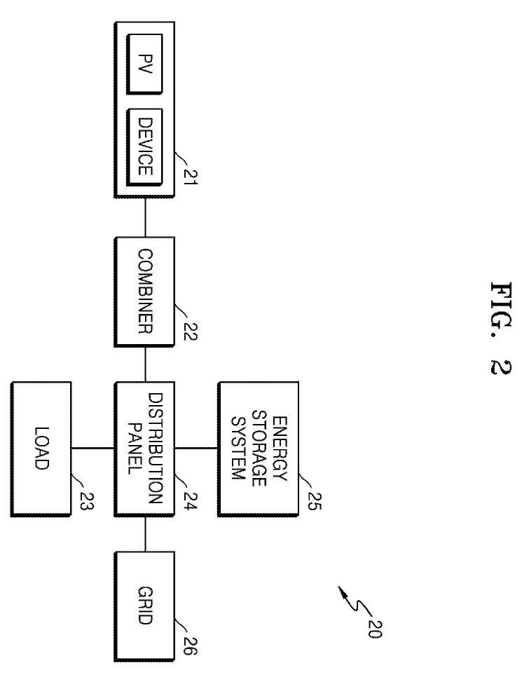

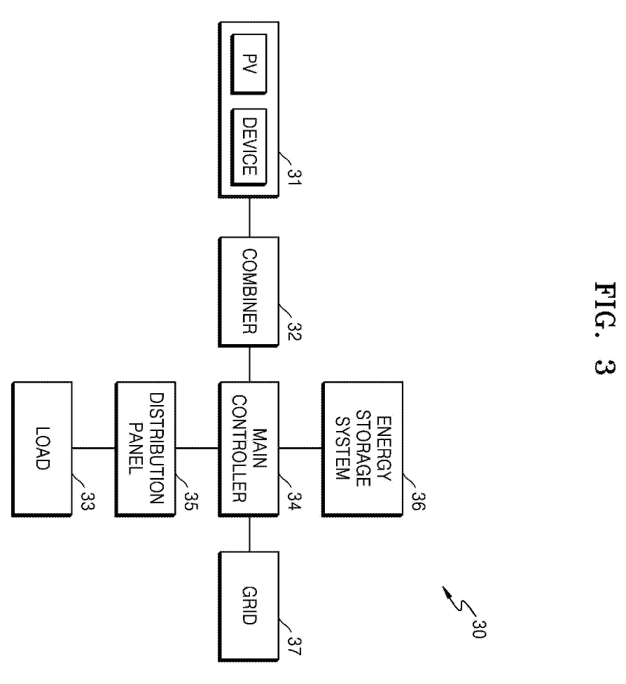

By combining at least some of the components described above, the power supply system 10 may be implemented in various forms. Hereinafter, various embodiments of the power supply system 10 will be described with reference to FIGS. 2 and 3. However, the implementation of the power supply system 10 is not limited to the embodiments described below.

FIG. 2 shows an example of a power supply system according to an embodiment.

Referring to FIG. 2, a power supply system 20 according to an embodiment may include a photovoltaic power generation device 21, a combiner 22, a load 23, a distribution panel 24, and an energy storage device 25. The power supply system 20 may be connected to an external power grid 26.

In an embodiment, the energy storage device 25 may be connected to the distribution panel 24 so as to be charged or discharged. In another embodiment, the energy storage device 25 may be connected to the combiner 22 so as to be charged or discharged.

As the energy storage device 25 is further provided in the power supply system 20, the power stored in the energy storage device 25 may be used to meet the power required by the load 23 in case that the photovoltaic power generation device 21 alone may not meet the power required by the load 23. In case that the power generated from the photovoltaic power generation device 21 exceeds generated energy for meeting the power required by the load 23, the amount of excess may be stored in the energy storage device 25. In case that a charge amount of the energy storage device 25 is not more than a threshold and the power generated from the photovoltaic power generation device 21 does not exceed the power required to meet the power required by the load 23, the energy storage device 25 may be charged with power supplied from the power grid 26.

In this way, the power supply system 20 may perform efficient power supply to the load 23 using the energy storage device 25.

The combiner 22 may control voltage, current and/or power output from the photovoltaic power generation device 21 according to a power supply state of the photovoltaic power generation device 21, the load 23, and/or the power grid 26, and set the operating mode of the combiner 22 to a diagnostic mode, a drive mode, etc.

The energy storage device 25 may control the voltage, current, and/or power supplied to or output from the energy storage device 25 according to the power supply state of the photovoltaic power generation device 21, the load 23, and/or power grid 26, and set the operating mode of the energy storage device 25 to the diagnostic mode, the drive mode, etc.

In an embodiment, the power supply system 20 may further include a sub-panel (not shown) connected to the distribution panel 24. At least one photovoltaic power generation device 21 may be connected to a sub-panel through the combiner 22, and at least one other photovoltaic power generation device 21 may be directly connected to the sub-panel.

At least one energy storage device 25 may be connected to the combiner 22, the distribution panel 24, or the sub-panel so as to be integrated into the power supply system 20.

At least one photovoltaic power generation device 21 and the distribution panel 24 may also be connected via a power path that does not include the combiner 22. For example, at least one photovoltaic power generation device 21 may be connected to the distribution panel 24 via the power path that does not include the combiner 22, while another at least one photovoltaic power generation device 21 may be connected to the distribution panel 24 through the combiner 22.

In an embodiment, at least one photovoltaic power generation device 21 may be connected to a sub-panel through the combiner 22, and at least one other photovoltaic power generation device 21 may be directly connected to the sub-panel.

The power supply system 20 may increase total generated energy of the photovoltaic power generation device 21 that may be integrated into the power supply system 20 by including the sub-panel that provides an additional capacity.

FIG. 3 shows an example of a power supply system according to another embodiment.

Referring to FIG. 3, a power supply system 30 according to an embodiment may include a photovoltaic power generation device 31, a combiner 32, a load 33, a main controller 34, a distribution panel 35, and an energy storage device 36. The power supply system 30 may be connected to an external power grid 37.

Meanwhile, the photovoltaic power generation device 31, the combiner 32, the load 33, and the energy storage device 36 shown in FIG. 3 may correspond to the photovoltaic power generation device 21, the combiner 22, the load 23, and the energy storage device 25 shown in FIG. 2, respectively. The main controller 34 shown in FIG. 3 may correspond to the main controller described above with reference to FIG. 1, respectively.

The combiner 32 may electrically connect at least one photovoltaic power generation device 31 and the main controller 34. For example, the combiner 32 may combine the power output from at least one photovoltaic power generation device 31 into single power and supply the single power to the main controller 34.

The main controller 34 may electrically connect the combiner 32, the distribution panel 35, and the power grid 37. The main controller 34 may connect the aforementioned components to an auxiliary power source such as the energy storage device 36 and/or an auxiliary power generation device (e.g., a diesel power generator, etc.). For example, the main controller 34 may output power supplied from the combiner 32 to the distribution panel 35, the energy storage device 36, and/or the power grid 37. The main controller 34 may output power supplied from the power grid 37 to the distribution panel 35 or the energy storage device 36. The main controller 34 may output power supplied from the energy storage device 36 to the distribution panel 35.

The distribution panel 35 may electrically connect the main controller 34 to at least one load 33. In this way, the power supply system 30 may supply power generated from the photovoltaic power generation device 31 to the load 33 through the distribution panel 35.

The power supply system 30 may integrate a plurality of energy storage devices 36 and/or auxiliary power generation devices into the power supply system 30 by including the main controller 34, thereby enabling stable power supply. Even in an off-grid environment where the power supply system 30 may not reliably receive power from the power grid 37, power may be stably supplied to the load 33 such as a backup load, etc.

Meanwhile, the main controller 34 may control the voltage, current, and/or power output from or supplied to each component based on the state of the photovoltaic power generation device 31, the load 33, the energy storage device 36, and/or the power grid 37, and set the operating mode of the photovoltaic power generation device 31 and/or the energy storage device 36 to the diagnostic mode, the operating mode, etc.

In an embodiment, the power supply system 30 may further include a sub-panel (not shown) connected to the main controller 34 and distinct from the distribution panel 35. At least one backup load among the loads 33 with a relatively high need for stable power supply may be connected to the sub-panel, and at least one non-backup load among the loads 33 with a relatively low need for stable power supply may be connected to the distribution panel 35.

The main controller 34 may electrically connect the combiner 32, the distribution panel 35, the energy storage device 36, the power grid 37, and the sub-panel. The main controller 34 may supply power supplied from the combiner 32, the energy storage device 36, and/or the power grid 37 to at least one non-backup load through the distribution panel 35, and supply the power to a backup load through the sub-panel.

In an embodiment, the power supply system 30 may further include a sub-panel connected to the main controller 34 and distinct from the distribution panel 35, and the power grid 37 may be connected to the distribution panel 35 instead of being connected to the main controller 34. The main controller 34 may electrically connect the combiner 32, the distribution panel 35, the energy storage device 36, and the sub-panel, and the distribution panel 35 may electrically connect the main controller 34, a non-backup load, and the power grid 37.

For example, the power supply system 30 may be implemented by connecting, to the combiner 32 and the energy storage device 36, the main controller 34 to the pre-installed distribution panel 35 for connecting at least one load 33 to the power grid 37.

In this way, even in the off-grid environment where the power supply system 30 may not reliably receive power from the power grid 37, power may be stably supplied to the load 33 such as a backup load, etc.

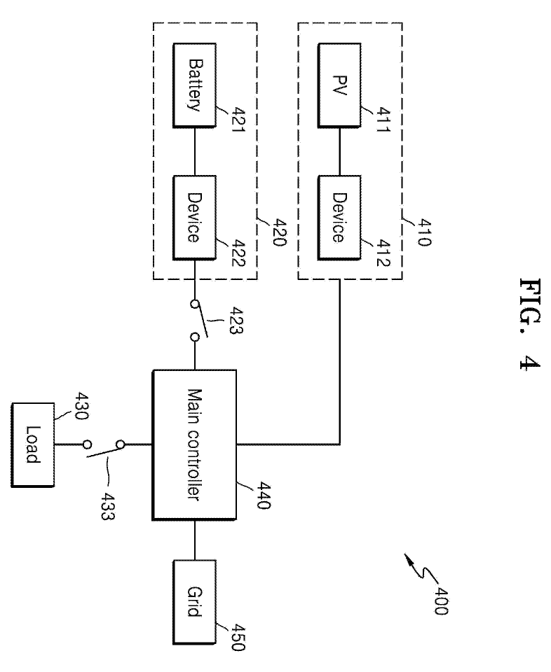

FIG. 4 is a view for describing an electrical connection relationship between components of a power supply system according to an embodiment.

Referring to FIG. 4, a power supply system 400 according to an embodiment may include a photovoltaic power generation device 410, an energy storage device 420, a load 430, and a main controller 440. The power supply system 400 may be connected to an external power grid 450.

The photovoltaic power generation device 410, an energy storage device 420, a load 430, and a main controller 440 shown in FIG. 4 may correspond to the photovoltaic power generation device 31, the energy storage device 36, the load 33, and the main controller 34 shown in FIG. 3, respectively.

As described above in FIGS. 1 to 3, the power supply system 400 may further include components such as a combiner and/or a distribution device (panel) as needed. For example, the power supply system 400 may include a combiner provided between the photovoltaic power generation device 410 and the main controller 440, and/or a distribution panel provided between the main controller 440 and the load 430, but the present disclosure is not limited thereto.

Referring to FIG. 4, the photovoltaic power generation device 410 may include a photovoltaic module 411 and a device 412. The device 412 may be a PCS that performs power conversion on the power generated from the photovoltaic module 411, as described in FIG. 1. In this case, the device 412 may convert the power output from the photovoltaic power generation device 410 based on a control signal generated by the main controller 440.

Referring to FIG. 4, the energy storage device 420 may include a battery 421 and a device 422. The device 422 may be a PCS that performs conversion between battery-side power and opposite-side power, as described in FIG. 1. In this case, the device 422 may convert the power output from the energy storage device 420 or the power supplied to the energy storage device 420, based on the control signal generated by the main controller 440.

Referring to FIG. 4, in an embodiment, the power supply system 400 may include a battery-side switch 423 for establishing/disconnecting an electrical connection between the battery 421 and the power supply system 400. Thus, in case that the battery-side switch 423 is open, the flow of power from the battery 421 to the power supply system 400 may be blocked, thereby preventing further discharge of the battery due to standby power and leakage current of the device 422.

The power supply system 400 may include a load-side switch 433 for establishing/disconnecting an electrical connection between the load 430 and the power supply system 400. Accordingly, in case that the load-side switch 433 is open, power supply from the battery 421 to the load 430 may be cut off, thereby preventing additional power consumption from the battery 421 due to standby power consumption of the load 430, minor power consumption caused by a residual load, etc.

In an embodiment, the battery-side switch 423 and the load-side switch 433 may be implemented using a relay, a semiconductor switch, etc., but are not limited thereto. For convenience of description, positions of the battery-side switch 423 and the load-side switch 433 are specified in FIG. 4, but the present disclosure is not limited thereto.

For example, the positions of the battery-side switch 423 and the load-side switch 433 may be modified depending on design and implementation methods of the power supply system 400. For example, the battery-side switch 423 may be arranged in an output of the battery 421. The load-side switch 433 may be positioned not only at a connection point with the load 430 but also at a position for controlling a specific load group within a power distribution panel.

Although not shown in FIG. 4, the power supply system 400 may include a switch between the battery 421 and the device 422 to block power consumption from the battery 421 due to standby power consumption of the device 422, as needed.

Meanwhile, although not shown in FIG. 4, the power supply system 400 may include a battery disconnect switch. Here, the battery disconnect switch may refer to a component for completely disconnecting the electrical connection between the battery and the power supply system based on the control signal from the main controller 440. For example, the main controller 440 may perform a rapid shutdown to completely isolate the battery from the power supply system by tripping the battery disconnect switch in response to a battery voltage of a first threshold value or less. To this end, the battery disconnect switch may be integrated into the BMS or provided within a battery pack, but is not limited thereto.

In an embodiment, the main controller 440 may monitor state information of at least one device included in the power supply system 400 and/or state information of an external power grid.

For example, the main controller 440 may obtain state information of the battery 421. The state information of the battery 421 may include information such as an SOC and/or current of the battery 421, but is not limited thereto.

As another example, the main controller 440 may obtain state information of the photovoltaic power generation device 410. The state information of the photovoltaic power generation device 410 may include information such as power generated from the photovoltaic power generation device 410, but is not limited thereto.

As another example, the main controller 440 may obtain state information of the load 430. Here, the state information of the load 430 may include, but is not limited to, information such as a power consumption state of the load 430, a load-specific power consumption pattern, and load-specific priorities regarding power supply.

As another example, the main controller 440 may obtain state information of the power grid 450. The state information of the power grid 450 may include information regarding a connection state (on-grid and off-grid) between the power supply system 400 and the external power grid 450 and information such as whether a power outage or failure has occurred in the power grid 450.

In an embodiment, the main controller 440 may control a power flow based on the state information of each component included in the power supply system 400.

For example, the main controller 440 may control the power flow to supply power stored in the energy storage device 420 to the load 430 in case that the photovoltaic power generation device 410 alone may not meet the power required by the load 430.

The main controller 440 may control the power flow to transmit power supplied from the power grid 450 to the load 430 in case that the photovoltaic power generation device 410 alone may not meet the power required by the load 430 and the power stored in the energy storage device 420 may be insufficient to supply the load 430.

The main controller 440 may control the power flow such that in case that the power generated from the photovoltaic power generation device 410 exceeds the generated energy for meeting the power required by the load 430, the excess may be stored in the energy storage device 420.

The main controller 440 may control the power flow to charge the energy storage device 420 using power supplied from the power grid 450 in case that the charge amount of the energy storage device 420 is less than or equal to a threshold and the power generated from the photovoltaic power generation device 410 does not exceed the power required to meet the load 430.

Meanwhile, in case that power continues to be output from the energy storage device 420, battery overdischarge may occur, where the voltage of the battery 421 drops below a normal minimum voltage. In this case, problems such as shortened battery life and unstable power supply from the power supply system 400 may occur, such that an operating method of the power supply system 400 for preventing overdischarge of the battery 421 may be required.

As described above, the power flow of the power supply system 400 may be dynamically changed depending on various factors such as load state, generated energy, grid connection, etc. Thus, an operating method of the power supply system 400 may be required to prevent overdischarge of the battery 421 and provide stable power supply by considering both the state information of the battery 421 and the operating state of the power supply system 400.

To prevent overdischarge of the battery 421, the main controller 440 may perform operations to adjust energy output from the battery 421, perform charging of the battery 421, change the electrical connection relationships between components of the power supply system 400, and completely isolate the battery 421 from the power supply system 400.

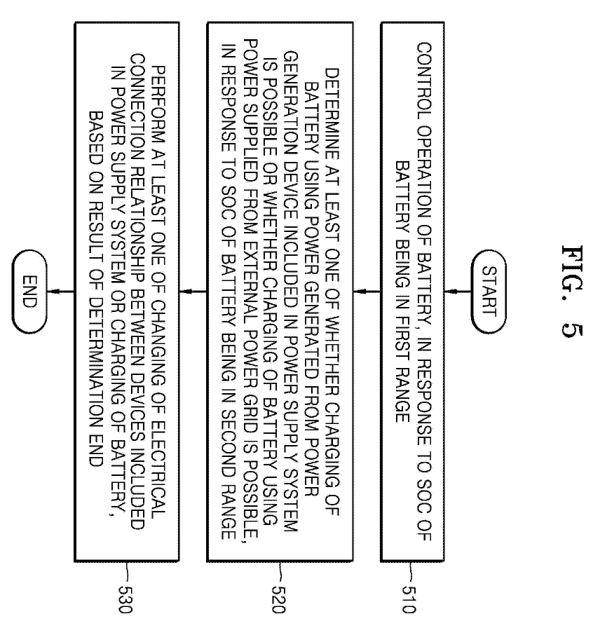

Hereinafter, with reference to FIGS. 5 through 8, a method for preventing overdischarge of a battery according to an embodiment will be described.

FIG. 5 is a flowchart of a method of preventing overdischarge of a battery according to an embodiment.

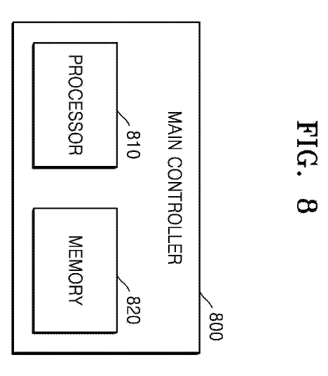

The method described below with reference to FIG. 5 may be performed by a main controller 800 of FIG. 8, and specifically, may be performed by a processor 810 included in the main controller 800.

Referring to FIG. 5, in operation 510, the processor may control the operation of the battery in response to the SOC of the battery being in a first range.

In an embodiment, the processor may control a power conversion device to stop discharging of the battery in response to the SOC of the battery being in the first range. Specifically, the processor may control the power conversion device to stop power supply from the battery to the load in response to the SOC of the battery being in the first range.

For example, the first range may be set as “SOC greater than 3 % and, less than or equal to 5 %.” In this case, the main controller may monitor whether the SOC of the battery is in the set first range, and in response to the SOC of the battery being in the first range, may control the battery-side PCS to adjust the power output to the load from the battery to 0.

In this regard, despite the power output from the battery being adjusted through PCS control, minute power may be continuously supplied to the load from the battery due to residual power, standby power consumption by the load, etc. Alternatively, the power output from the battery may not be adjusted due to a failure/error of the PCS, etc. To address this problem, the processor may disconnect the electrical connection between the power supply system and at least one load included in the power supply system.

That is, in an embodiment, the processor may further perform an operation to disconnect the electrical connection between the power supply system and at least one load included in the power supply system in response to the SOC of the battery being in the first range. The processor may perform an operation to disconnect the electrical connection between the power supply system and the at least one load included in the power supply system together with or sequentially with the control operation of the battery-side PCS described above.

Meanwhile, in a situation where the power supplied from the external power grid is available, there is a need to use the power supplied from the external power grid to meet the power required by the load. In this case, an electrical connection needs to be established between the power supply system and the at least one load included in the power supply system. Thus, the processor may further perform an operation of determining whether to disconnect the electrical connection between the load and the power supply system by considering the availability of the power supplied from the power grid.

That is, in an embodiment, the processor may determine whether the power supplied from the external power grid is available, and disconnect the electrical connection between the power supply system and the load in case that the power supplied from the external power grid is not available.

The situation where the power supplied from the external power grid is available may include a situation where the power supply system and the external power grid are connected and the power from the external power grid is smoothly supplied.

In an embodiment, the processor may determine the situation, based on information regarding the connection state (on-grid and off-grid) between the power supply system and the external power grid, state information of the external power grid such as whether power outage or failure has occurred in the power grid 450.

For example, the processor may determine that the power supplied from the power grid is not available in case that the power supply system is not connected to the external power grid. As another example, the processor may determine that the power supplied from the power grid is not available in case that the power supply system may not use the power supplied from the external power grid in the event of a grid outage or failure even when the power supply system is connected to the external power grid.

In an embodiment, the availability of the power supplied from the external power grid may be determined based on an initial setting value input by a user. In this case, the user may input the initial setting value into the main controller, and the processor may also determine the availability of the power supplied from the power grid, based on the initial setting value input by the user.

For example, the main controller may provide a user with an option selection function to set whether the power supply system operates in an on-grid environment or an off-grid environment, and the user may input an initial setting value to the main controller through this function.

In operation 520, the processor may determine whether the battery may be charged using power generated from a power generation device included in the power supply system or whether the battery may be charged using power supplied from an external power grid, in response to the SOC of the battery being in a second range.

Here, the second range may include a third range serving as a reference for charging the battery using the power generation device and a fourth range serving as a reference for charging the battery using the external power grid. For example, in case that the second range corresponds to “SOC of at least 0%, but less than or equal to 3%,” the third range may be set as “SOC greater than 0%, but less than or equal to 3%,” and the fourth range may be set as “SOC of 0%.”

In an embodiment, the processor may determine whether the battery may be charged using power generated from the power generation device included in the power supply system in response to the SOC of the battery being in the third range.

The third range according to an embodiment may be set as a section of SOC in a range lower than the first range. That is, in an embodiment, in spite of an operation being performed in response to the SOC of the battery being in the first range, as the SOC of the battery continues to decrease and subsequently is in the third range, the processor may perform the operation described below.

For example, the third range may be set as “SOC greater than 0%, but less than or equal to 3%.” In this case, the processor may monitor whether the SOC of the battery is in the set third range. The processor may determine whether the battery may be charged using power generated from the power generation device included in the power supply system in response to the SOC of the battery being in the third range.

In an embodiment, the processor may determine whether the battery may be charged using the power generated from the power generation device based on selected conditions regarding energy produced by the power generation device.

For example, the processor may determine that charging of the battery using the power generated from the power generation device is possible in case that the power generated from the power generation device satisfies the selected conditions. In this case, the power generated from the power generation device may be primarily used for battery charging before being supplied to the load.

In an embodiment, the processor may determine whether the battery may be charged using the power generated from the power generation device based on selected conditions regarding energy produced by the power generation device and a load demand.

For example, the processor may determine that charging of the battery using the power generated from the photovoltaic power generation device is possible in case that a selected condition is satisfied that the power generated from the power generation device exceeds the load demand.

As a specific example, the processor may determine that charging of the battery using the power generated from the photovoltaic power generation device is possible in case that a selected condition is satisfied that the power generated from the power generation device exceeds a load demand of the backup load.

Furthermore, in an embodiment, the selected condition may be set differently depending on the availability of power supplied from the external power grid.

For example, in case that the power supplied from the external power grid is available, the processor may determine whether the battery may be charged using the power generation device based on the selected condition that the power generated from the power generation device exceeds the load demand. At this time, as previously described, the selected condition may include a condition that the power generated from the power generation device exceeds the load demand of the backup load.

As another example, in case that the power supplied from the external power grid is not available, the processor may determine whether the battery may be charged using the power generation device based on a selected condition that there is the power generated from the power generation device.

In an embodiment, the processor may determine whether the battery may be charged using the power generated from the external power grid in response to the SOC of the battery being in the fourth range.

The fourth range according to an embodiment may be set as a section of SOC in a range lower than the third range. That is, in an embodiment, in spite of an operation being performed in response to the SOC of the battery being in the third range, as the SOC of the battery continues to decrease and subsequently is in the fourth range, the processor may perform the operation described below. Accordingly, as an operation to be performed in response to SOC decrease, battery charging using the power generation device and battery charging using the external power grid may be performed stepwisely, thereby reducing the usage of the external power grid.

For example, the fourth range may be set as “SOC 0%.” In this case, the main controller may monitor whether the SOC of the battery is in the set fourth range. The processor may determine whether the battery may be charged using the power generated from the external power grid in response to the SOC of the battery being in the fourth range.

In an embodiment, as described above, the processor may determine whether the battery may be charged using the power supplied from the external power grid, based on state information of the power grid.

In operation 530, the processor may perform at least one of changing an electrical connection relationship between devices included in the power supply system or charging the battery, based on a determination result of operation 520.

In an embodiment, the processor may charge the battery using the power generated from the power generation device in response to determining that charging of the battery using the power generated from the power generation device is possible. The processor may disconnect the electrical connection between the battery and the power supply system in response to determining that charging of the battery using the power generated from the power generation device is not possible.

That is, in case that the SOC of the battery is within the third range and the battery may be charged using the power generated from the power generation device, the battery may be charged using the power generation device, thereby preventing the battery from being overdischarged. On the other hand, in case that the SOC of the battery is in the third range and charging of the battery using the power generated from the power generation device is not possible, the electrical connection between the battery and the power supply system is disconnected to limit additional discharge of the battery, thereby preventing overdischarge of the battery.

In an embodiment, the processor may charge the battery using the power generated from the power grid in response to determining that charging of the battery using the power supplied from the power grid is possible.

That is, in case that the SOC of the battery is in the fourth range and charging of the battery using the power supplied from the external power grid is possible, the battery may be charged using the external power grid, thereby preventing the battery from being overdischarged.

On the other hand, in case that the SOC of the battery is in the fourth range and charging of the battery using the power supplied from the external power grid is not possible, the electrical connection between the battery and the power supply system is disconnected to limit additional discharge of the battery, thereby preventing overdischarge of the battery.

Meanwhile, in an embodiment, the processor may further perform an operation of changing an operating mode of the battery-side PCS to a power-saving mode in case that the processor determines that charging of the battery is not possible according to operation 520. Here, the power-saving mode may refer to a mode in which the PCS operates to minimize standby power consumption while no battery charging or discharging operations are performed. Accordingly, it is possible to prevent a situation where an unnecessary power loss occurs due to standby power consumption of the PCS or leakage current from other internal circuits, even in case that battery charging is impossible and thus no PCS operation is required.

Furthermore, the operation of changing the operating mode of the PCS may be performed simultaneously with or before or after operation 530. For example, the operation of changing the operating mode of the PCS may be performed simultaneously with or before or after the operation of disconnecting the electrical connection between the battery and the power supply system according to operation 530.

In an embodiment, the first to fourth ranges regarding the SOC of the battery described above may be set differently depending on the availability of power supplied from the external power grid.

For example, in case that power supplied from the external power grid is available, charging of the battery using the external power grid is possible, such that the first to fourth ranges may be set to have less values than a case where the power supplied from the external power grid is unavailable.

As another example, in case that the power supplied from the external power grid is available, the processor may allow changes to setting values of the first through fourth ranges based on a user input. On the other hand, in case that the power supplied from the external power grid is unavailable, the processor may restrict changes to the first to fourth ranges based on the user input and set the first to fourth ranges to predefined fixed values.

Once the SOC of the battery reaches 0%, it may become impossible to measure a discharge level of the battery through SOC monitoring despite continuous discharge of the battery. In this case, voltage information of the battery may be used as a criterion for determining whether to finally disconnect the electrical connection between the battery and the power supply system.

Although not shown in FIG. 5, in one embodiment, the processor may, in response to determining that the battery is not capable of charging, compare the voltage of the battery to the first threshold value. Additionally, the processor may disconnect the electrical connection between the battery and the power supply system in response to the voltage of the battery being the first threshold value or less.

That is, when the voltage of the battery reaches the first threshold, the electrical connection between the battery and the power supply system is finally cut off, thereby preventing overdischarge of the battery. Additionally, the processor may trip the battery disconnect switch to finally disconnect the electrical connection between the battery and the power supply system.

In an embodiment, the processor may output notification information to the user before the voltage of the battery reaches the first threshold value, thereby disconnecting the electrical connection between the battery and the power supply system.

Specifically, the processor may compare the voltage of the battery with a second threshold value. The processor may output notification information in response to the voltage of the battery reaching the second threshold value. Here, the second threshold value may include a value greater than the first threshold value. Accordingly, the notification information may be output to the user before the electrical connection between the battery and the power supply system is finally disconnected.

The first threshold value according to an embodiment may be set to a value less than a voltage corresponding to a lower limit SOC of the fourth range described above. The second threshold value according to an embodiment may be set to a value less than the voltage corresponding to the lower limit SOC of the fourth range, but greater than the first threshold value. For example, in case that the lower limit SOC of the fourth range is 0 %, and the voltage of the battery at an SOC of 0 % is 2.8 V, the first threshold value may be set to 2.6 V and the second threshold value to 2.7 V, but the present disclosure is not limited thereto.

The operation of finally disconnecting the electrical connection between the battery and the power supply system based on the voltage of the battery may be performed in parallel with or after operation 530. For example, the operation of ultimately disconnecting the electrical connection between the battery and the power supply system based on the voltage of the battery may be performed in case that the processor determines in operation 520 that charging of the battery is not possible. As another example, the operation of finally disconnecting the electrical connection between the battery and the power supply system based on the voltage of the battery may be performed in case that the voltage of the battery continues to drop despite changing of the electrical connection relationship between devices included in the power supply system or charging of the battery in operation 530.

Although not shown in FIG. 5, the processor may obtain the SOC and the voltage information of the battery at regular time intervals before operation 510. For example, the processor may perform the foregoing operations by obtaining, at regular time intervals, at least one of SOC information of the battery, voltage information of the battery, state information of at least one component included in the power supply system, or state information of the power grid.

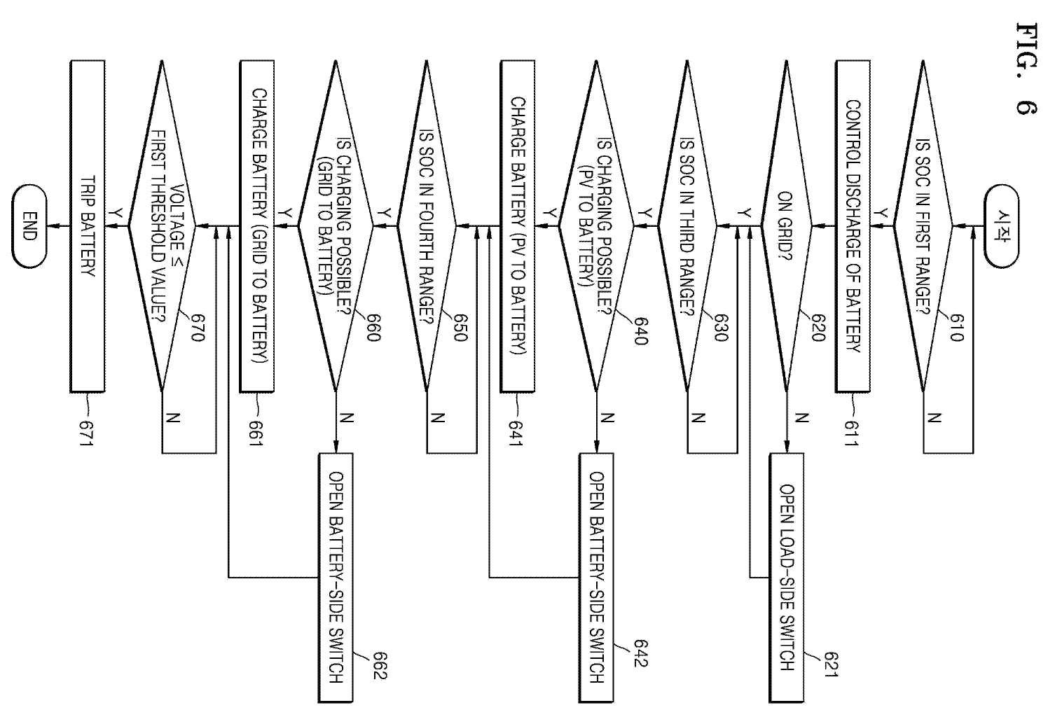

FIG. 6 is a flowchart of a method of preventing overdischarge of a battery according to an embodiment.

The method described below with reference to FIG. 6 may be performed by a main controller 800 of FIG. 8, and specifically, may be performed by a processor 810 included in the main controller 800.

Referring to FIG. 6, in operations 610 and 611, the processor may monitor whether the SOC of the battery is in the first range. The processor may control a power conversion device to stop discharging of the battery in response to the SOC of the battery being in the first range.

In operation 620, the processor may determine the availability of power supplied from the external power grid.

In operation 621, the processor may open the load-side switch in response to determining that the power supplied from the external power grid is unavailable, thereby disconnecting the electrical connection between the load and the power supply system.

In operation 630, after the processor determines that the power supplied from the external power grid is available according to operation 620, the processor may monitor whether the SOC of the battery is in the third range. Alternatively, after opening the load-side switch in operation 621, the processor may continue to monitor whether the SOC of the battery is in the third range in operation 630.

In operation 640, the processor may determine whether the battery may be charged using the power generated from the power generation device in response to the SOC of the battery being in the third range.

In operation 641, the processor may charge the battery using the power generated from the power generation device in response to determining that charging of the battery using the power generated from the power generation device is possible.

In operation 642, the processor may open the battery-side switch in response to determining that charging of the battery using the power generation device is impossible, thereby disconnecting the electrical connection between the battery and the power supply system.

In operation 650, the processor may charge the battery using the power generated from the power generation device according to operation 641, while continuing to monitor whether the SOC of the battery is in the fourth range. Alternatively, after opening the battery-side switch in operation 642, the processor may continue to monitor whether the SOC of the battery is in the fourth range.

In operation 660, the processor may determine whether the battery may be charged using the external power grid in response to the SOC of the battery being in the fourth range.

In operation 661, the processor may charge the battery using the power supplied from the external power grid in response to determining that charging of the battery using the external power grid is possible.

Meanwhile, the battery charging operation according to operation 661 may further include an operation of short-circuiting the battery-side switch to perform charging. For example, it is assumed that the SOC of the battery is in the third range, but charging of the battery using the power generation device is impossible, resulting in the battery-side switch remaining open. In this case, unless the battery is charged, the SOC of the battery may continuously decrease, potentially causing the SOC of the battery to be in the fourth range. In this situation, in case that the processor determines that charging of the battery using the external power grid is possible according to operation 660, the processor may short-circuit the battery-side switch before performing charging of the battery.

In operation 662, the processor may open the battery-side switch in response to determining that charging of the battery using power supplied from the external power grid is impossible.

Meanwhile, the battery-side switch may be already open before operation 662 is performed. For example, as described above, it is assumed that the SOC of the battery is in the third range, but charging of the battery using the power generation device is impossible, resulting in the battery-side switch remaining open. In this case, unless the battery is charged, the SOC of the battery may continuously decrease, potentially causing the SOC of the battery to be in the fourth range. In this situation, in case that the processor determines that charging of the battery using the external power grid is impossible according to operation 660, the processor may maintain the open state of the battery-side switch.

In operation 670, the processor may charge the battery using the power supplied from the external power grid according to operation 661, while continuing to monitor whether the voltage of the battery is the first threshold value or less. Alternatively, after opening the battery-side switch according to operation 662, the processor may continue to monitor whether the voltage of the battery is the first threshold value or less.

In operation 671, the processor may finally trip the battery in response to the voltage of the battery being the first threshold value or less.

According to the described embodiment, by performing an overdischarge prevention operation corresponding to a charging depth or voltage of the battery in a stepwise manner, overdischarge of the battery may be effectively prevented while simultaneously ensuring power supply stability. Furthermore, by minimizing forced battery charging using the power supplied from the external power grid, electricity charges imposed on the user may be reduced.

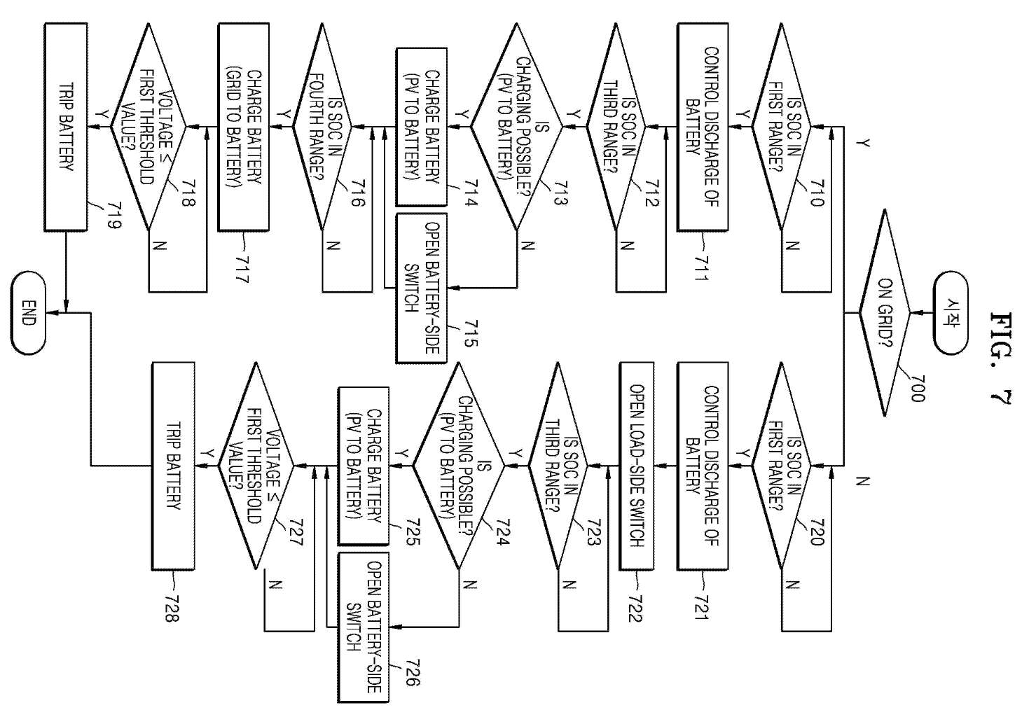

FIG. 7 is a flowchart of a method of preventing overdischarge of a battery according to another embodiment.

The method described below with reference to FIG. 7 may be performed by a main controller 800 of FIG. 8, and specifically, may be performed by a processor 810 included in the main controller 800.

As shown in FIG. 7, in an embodiment, the processor may first determine the availability of the power supplied from the external power grid and, based on the determination result, may perform selected operations described below.

Specifically, referring to FIG. 7, in operation 700, the processor may determine the availability of the power supplied from the external power grid.

First, it is assumed that in operation 700, the processor determines that the power supplied from the external power grid is available.

In operations 710 and 711, the processor may monitor whether the SOC of the battery is in the first range, and in response to the SOC of the battery being in the first range, control the power conversion device to stop discharging of the battery.

Meanwhile, as mentioned above, in case that the power supplied from the power grid is available and the SOC of the battery is a threshold level or less, the power supplied from the power grid may be used to meet the load demand. Thus, an operation of opening the load-side switch may be omitted.

In operations 712 and 713, the processor may monitor whether the SOC of the battery is in the third range, and determine whether charging of the battery using the power generation device is possible in response to the SOC of the battery being in the third range.

In operation 714, the processor may perform charging of the battery using the power generation device in response to determining that the SOC of the battery being in the third range and that charging of the battery using the power generation device is possible.

In operation 715, the processor may open the battery-side switch in response to determining that the SOC of the battery being in the third range and that charging of the battery using the power generation device is impossible.

In operation 716, the processor may charge the battery using the power generated from the power generation device according to operation 714, while continuing to monitor whether the SOC of the battery is in the fourth range. Alternatively, after opening the battery-side switch in operation 715, the processor may continue to monitor whether the SOC of the battery is in the fourth range.

In operation 717, the processor may perform charging of the battery using the external power grid in response to the SOC of the battery being in the fourth range. In this case, as it is already determined in operation 700 that the external power grid is available, the operation of determining whether charging of the battery using the external power grid may be omitted.

In operations 718 and 719, the processor may charge the battery using the power supplied from the external power grid according to operation 717, while continuing to monitor whether the voltage of the battery is the first threshold value or less. The processor may finally disconnect the electrical connection between the battery and the power supply system in response to the voltage of the battery being the first threshold value or less.

Next, it is assumed that in operation 700, the processor determines that the power supplied from the external power grid is unavailable.

In operations 720 and 721, the processor may monitor whether the SOC of the battery is in the first range, and in response to the SOC of the battery being in the first range, control the power conversion device to stop discharging of the battery.

In operation 722, the processor may disconnect the electrical connection between the power supply system and the load by opening the load-side switch. In this case, as it is already determined in operation 700 that the external power grid is unavailable, the operation of determining whether charging of the battery using the external power grid may be omitted.

In operations 723 and 724, the processor may monitor whether the SOC of the battery is in the third range, and determine whether charging of the battery using the power generation device is possible in response to the SOC of the battery being in the third range.

In operation 725, the processor may perform charging of the battery using the power generation device in response to determining that the SOC of the battery being in the third range and that charging of the battery using the power generation device is possible.

In operation 726, the processor may open the battery-side switch in response to determining that the SOC of the battery being in the third range and that charging of the battery using the power generation device is impossible.

In operations 727 and 728, the processor may charge the battery using the power generated from the power generation device according to operation 725, while continuing to monitor whether the voltage of the battery is the first threshold value or less. Alternatively, after opening the battery-side switch according to operation 726, the processor may continue to monitor whether the voltage of the battery is the first threshold value or less. The processor may disconnect the electrical connection between the battery and the power supply system in response to the voltage of the battery being the first threshold value or less.

According to the described embodiment, by stepwisely performing an overdischarge prevention operation for the battery based on whether the power supplied from the power grid is available, overdischarge of the battery may be effectively prevented while simultaneously ensuring power supply stability. Furthermore, by minimizing forced battery charging using the power supplied from the external power grid, electricity charges imposed on the user may be reduced.

FIG. 8 is a block diagram of a main controller according to an embodiment.

Referring to FIG. 8, a main controller 800 may include a processor 810 and a memory 820. Components related to the embodiment are shown in the main controller 800 of FIG. 8. Accordingly, those of ordinary skill in the art may understand that other general-purpose components may be included in addition to the components shown in FIG. 8. For example, although not shown in FIG. 8, the main controller 800 may include a communication unit for receiving voltage or current sensing information that is fundamental data for obtaining power consumption and an interface unit enabling interaction with the user.

The processor 810 may control the overall operation of the main controller 800. For example, the processor 810 may control overall components included in the memory 820, etc., by executing programs stored in the memory 820. The processor 810 may control the operation of the main controller 800 by executing the programs stored in the memory 820.

The processor 810 may control at least some of the operations of the main controller 800 described above in FIGS. 1 to 7. For example, the processor 810 may control the operation of the battery in response to the SOC of the battery being in the first range, and determine at least one of whether the battery may be charged using the power generated from the power generation device included in the power supply system or whether the battery may be charged using the power supplied from the external power grid, in response to the SOC of the battery being in the second range, and control at least a part of an operation of changing the electrical connection relationship between the devices included in the power supply system or performing charging of the battery, based on the determination result.

Meanwhile, a specific example of the processor 810 operating may be identical to that described above with reference to FIGS. 1 to 7. Therefore, the following description will not include a detailed description of the operation of the processor 810.

The processor 810 may be implemented using at least one of application specific integrated circuits (ASICs), digital signal processors (DSPs), digital signal processing devices (DSPDs), programmable logic devices (PLDs), field programmable gate arrays (FPGAs), controllers, microcontrollers, microprocessors, and other electrical units for performing functions.

In an embodiment, the main controller 800 may be an electronic device having mobility. For example, the main controller 800 may be implemented as a smartphone, a tablet personal computer (PC), a PC, a smart television (TV), a personal digital assistant (PDA), a laptop, a media player, a navigation device, a camera-equipped device, or other mobile electronic devices. The main controller 800 may be implemented as a wearable device such as a watch, glasses, a hair band, a ring, etc., having a communication function and a data processing function.

In another embodiment, the main controller 800 may be an electronic device embedded in a circuit of the power supply system. For example, the main controller 800 may be an electronic device inserted into the circuit of the power supply system through tuning after a production process. Specifically, the main controller 800 according to an embodiment may be the main controller or distribution device shown in FIG. 1.

In another embodiment, the main controller 800 may be a server located outside the power supply system. A server may be implemented as a computer device or a plurality of computer devices that communicate over the network to provide commands, codes, files, contents, services, etc.

In yet another embodiment, the process performed in the main controller 800 may be performed by at least some of an electronic device having mobility, an electronic device embedded in a circuit of a power supply system, and a server located outside the power supply system.

According to means for solving the problems described above, by performing battery protection operations while comprehensively considering the operational state of the power supply system such as fluctuations in generated energy, load conditions, whether the power grid is interconnected, etc., thereby achieving both battery protection and the stability of power supply.

According to means for solving the problems of the present disclosure described above, the battery protection operation may be subdivided stepwisely, thereby efficiently and effectively preventing overdischarge of the battery in response to various scenarios.

An embodiment of the present disclosure may be implemented in the form of a computer program executable on a computer through various components, and the computer program may be recorded on a computer-readable medium. The medium may include a hardware device specially configured to store and execute a program instruction, like a magnetic medium such as a hard disk, a floppy disk, and a magnetic tape, an optical recording medium such as a CD-ROM and a DVD, a magneto-optical medium such as a floptical disk, ROM, RAM, flash memory, etc.

Meanwhile, the computer program may be a program command specially designed and configured for the present disclosure or a program command known to be used by those of ordinary skill in the art of the computer software field. Examples of the computer program may include not only a machine language code created by a complier, but also a high-level language code executable by a computer using an interpreter.

According to an embodiment, a method according to various embodiments of the present disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., Play Store^{TM}), or between two user devices directly. In the case of online distribution, at least a part of a computer program product may be at least temporarily stored in a machine-readable storage medium such as a memory of a server of a manufacturer, a server of an application store, or a relay server, or may be generated temporarily.

If there is no apparent description of the order of operations constituting the method according to the embodiments or a contrary description thereof, the operations may be performed in an appropriate order. However, the present disclosure is not necessarily limited according to the describing order of the operations. The use of all examples or exemplary terms in the present disclosure are to simply describe the present disclosure in detail, and unless the range of the present disclosure is not limited by the examples or the exemplary terms unless limited by the claims. Numerous modifications and adaptations will be readily apparent to one of ordinary skill in the art without departing from the spirit and scope of the appended claims or their equivalents.

Thus, the spirit of the present disclosure should not be determined by being limited to the above-described embodiments, and not only the claims to be described later, but also any range equivalent to or equivalently changed from the claims falls within the scope of the spirit of the present disclosure.

What is claimed is:

1. A method of preventing overdischarge of a battery in a power supply system, the method comprising:
controlling an operation of the battery in response to a state of charge (SOC) of the battery being in a first range;
determining at least one of whether charging of the battery using power generated from a power generation device included in the power supply system is possible or whether charging of the battery using power supplied from an external power grid is possible, in response to the SOC of the battery being in a second range; and
performing, based on a result of the determining, at least one of changing of an electrical connection relationship between devices included in the power supply system or charging of the battery.

2. The method of claim 1, wherein the controlling comprises controlling a power conversion device to stop discharge of the battery, in response to the SOC of the battery being in the first range.

3. The method of claim 1, wherein the controlling further comprises disconnecting an electrical connection between the power supply system and at least one load included in the power supply system, in response to the SOC of the battery being in the first range.

4. The method of claim 3, wherein the disconnecting further comprises:
determining whether the power supplied from the external power grid is available; and
determining, based on a result of the determining of whether the power supplied from the external power grid is available, whether to disconnect the electrical connection between the power supply system and the at least one load.

5. The method of claim 1, wherein the determining comprises determining whether charging of the battery using the power generated from the power generation device is possible, in response to the SOC of the battery being in a third range.

6. The method of claim 5, wherein the performing comprises charging the battery using the power generated from the power generation device, in response to determining that charging of the battery using the power generated from the power generation device is possible.

7. The method of claim 5, wherein the performing comprises disconnecting the electrical connection between the battery and the power supply system, in response to determining that charging of the battery using the power generated from the power generation device is impossible.

8. The method of claim 1, wherein the determining comprises determining whether charging of the battery using the power supplied from the external power grid is possible, in response to the SOC of the battery being in a fourth range.

9. The method of claim 8, wherein the performing comprises charging the battery using the power supplied from the external power grid, in response to determining that charging of the battery using the power supplied from the external power grid is possible.

10. The method of claim 1, further comprising changing an operating mode of a power conversion device, in response to determining that charging of the battery is impossible.

11. The method of claim 1, further comprising:
comparing a voltage of the battery with a first threshold value, in response to determining that charging of the battery is impossible; and
tripping a battery disconnect switch, in response to the voltage of the battery reaching the first threshold value.

12. The method of claim 11, further comprising, before the tripping, outputting notification information, in response to the voltage of the battery reaching a second threshold value,
Wherein the second threshold value comprises a value greater than the first threshold value.

13. The method of claim 1, further comprising, before the determining, obtaining at least one of SOC information of the battery, voltage information of the battery, state information of at least one component included in the power supply system, or state information of the external power grid, at regular time intervals.

14. A computer-readable recording medium having recorded thereon a program for causing a computer to execute the method of claim 1.

15. An apparatus for preventing overdischarge of a battery in a power supply system, the apparatus comprising:
at least one memory; and
at least one processor,
wherein the at least one processor is configured to:
control an operation of the battery, in response to a state of charge (SOC) of the battery being in a first range;
determine at least one of whether charging of the battery using power generated from a power generation device included in the power supply system is possible or whether charging of the battery using power supplied from an external power grid is possible, in response to the SOC of the battery being in a second range; and
perform, based on a result of the determination, at least one of changing of an electrical connection relationship between devices included in the power supply system or charging of the battery.

16. The apparatus of claim 15, wherein the at least one processor is further configured to determine whether charging of the battery using the power generated from the power generation device is possible, in response to the SOC of the battery being in a third range.

17. The apparatus of claim 16, wherein the at least one processor is further configured to charge the battery using the power generated from the power generation device, in response to determining that charging of the battery using the power generated from the power generation device is possible.

18. The apparatus of claim 16, wherein the at least one processor is further configured to disconnect the electrical connection between the battery and the power supply system, in response to determining that charging of the battery using the power generated from the power generation device is impossible.

19. The apparatus of claim 15, wherein the at least one processor is further configured to determine whether charging of the battery using the power supplied from the external power grid is possible, in response to the SOC of the battery being in a fourth range.

20. The apparatus of claim 19, wherein the at least one processor is further configured to charge the battery using the power supplied from the external power grid, in response to determining that charging of the battery using the power supplied from the external power grid is possible.
